(19) United States
(12) Patent Application Publication
(10) Pub. No.: US 2026/0024959 A1
(43) Pub. Date: Jan. 22, 2026

(54) WAVELENGTH BEAM COMBINING DEVICE, DIRECT DIODE LASER DEVICE, AND LASER PROCESSING MACHINE

(71) Applicant: NICHIA CORPORATION, Anan-shi (JP)

(72) Inventors: Takuya TSUJIMOTO, Yokohama-shi (JP); Norihiro DEJIMA, Yokohama-shi (JP)

(73) Assignee: NICHIA CORPORATION, Anan-shi (JP)

(21) Appl. No.: 19/264,950

(22) Filed: Jul. 10, 2025

(30) Foreign Application Priority Data
Jul. 17, 2024 (JP) 2024-114150

(51) Int. Cl. H01S 5/40; B23K 26/06; G02B 5/18; G02B 27/28

(52) U.S. Cl. CPC H01S 5/4087; B23K 26/0604; G02B 5/1861; G02B 27/283; H01S 5/4012

(57) ABSTRACT

A wavelength beam combining device for combining a plurality of laser beams having mutually different peak wavelengths includes: a diffraction grating that diffracts a plurality of first polarized beams linearly polarized in a first polarization direction and a plurality of second polarized beams linearly polarized in the first polarization direction. The plurality of first polarized beams and the plurality of second polarized beams are incident on an irradiation region of the diffraction grating in symmetry with respect to a reference plane including a normal line of the irradiation region and parallel to the first polarization direction, and the diffraction grating has a symmetrical structure with respect to the reference plane in the irradiation region, and combines the plurality of first polarized beams and the plurality of second polarized beams incident on the irradiation region in a direction parallel to the normal line to form a wavelength-combined beam.

### CROSS REFERENCE TO RELATED APPLICATION

This application claims priority to Japanese Patent Applications No. 2024-114150, filed on Jul. 17, 2024, the entire contents of which are hereby incorporated by reference.

### BACKGROUND

### Technical Field

The present disclosure relates to a wavelength beam combining device, a direct diode laser device, and a laser processing machine.

### Background Art

High-power and high-brightness laser beams are used to perform processing such as cutting, drilling, and marking on various types of materials or weld metal materials. Some of carbon dioxide gas laser devices and YAG solid-state laser devices that have been used for such laser processing are being replaced with fiber laser devices with high energy conversion efficiency. A laser diode (hereinafter, simply referred to as an LD) is used for a pump light source of the fiber laser device. In recent years, with an increase in the output of an LD, technologies are being developed to use an LD not as a pump light source but as a light source of a laser beam with which a material is directly irradiated to process the material. Such a technology is referred to as a direct diode laser (DDL) technology.

U.S. Pat. No. 6,192,062 discloses an example of a light source device that increases a light output by combining a plurality of laser beams emitted from a plurality of LDs and having mutually different peak wavelengths. Coaxial combining of a plurality of laser beams having mutually different wavelengths is referred to as “wavelength beam combining (WBC)” or “spectral beam combining (SBC)” and may be used to increase the light output and brightness of, for example, a DDL device.

Japanese Patent Publication No. H08-152580 A discloses a polarized light separating and synthesizing device that uniforms mixed polarization directions of light to extract the light in a uniform polarization direction.

### SUMMARY

A wavelength beam combining device that combines a plurality of laser beams having mutually different peak wavelengths is required to reduce its internal optical loss.

In an embodiment, a wavelength beam combining device of the present disclosure is a wavelength beam combining device that combines a plurality of laser beams having mutually different peak wavelengths and includes a diffraction grating configured to diffract a plurality of first polarized beams linearly polarized in a first polarization direction and a plurality of second polarized beams linearly polarized in the first polarization direction, the plurality of first polarized beams and the plurality of second polarized beams being obtained from the plurality of laser beams, wherein the plurality of first polarized beams and the plurality of second polarized beams are incident on an irradiation region of the diffraction grating in symmetry with respect to a reference plane including a normal line of the irradiation region and parallel to the first polarization direction, and the diffraction grating has a symmetrical structure with respect to the reference plane in the irradiation region, and combines the plurality of first polarized beams and the plurality of second polarized beams incident on the irradiation region in a direction parallel to the normal line to form a wavelength-combined beam.

In an embodiment, a direct diode laser device of the present disclosure includes the above wavelength beam combining device, and a plurality of semiconductor laser devices, each of which is configured to emit laser light corresponding to one of the plurality of laser beams.

In an embodiment, a laser processing machine of the present disclosure includes at least one direct diode laser device described above, an optical transmission fiber into which the wavelength-combined beam emitted from the at least one direct diode laser device is combined, and a processing head connected to the optical transmission fiber.

An embodiment of the present disclosure can reduce optical loss in a wavelength beam combining device.

### BRIEF DESCRIPTION OF DRAWINGS

FIG. 1 is a view schematically illustrating a configuration of a wavelength beam combining device according to an exemplary embodiment of the present disclosure.

FIG. 2 is a view schematically illustrating an example of a configuration of a diffraction grating.

FIG. 3 is a view schematically illustrating a configuration of a modified example of the wavelength beam combining device.

FIG. 4A is a side view schematically illustrating a configuration of a modified example of the diffraction grating.

FIG. 4B is another side view schematically illustrating the configuration of the modified example of the diffraction grating.

FIG. 4C is a top view schematically illustrating the configuration of the modified example of the diffraction grating.

FIG. 5 is a view schematically illustrating a configuration of another modified example of the diffraction grating.

FIG. 6 is a view schematically illustrating a configuration of a DDL device according to the exemplary embodiment of the present disclosure.

FIG. 7 is a view illustrating a configuration of a laser processing machine according to the exemplary embodiment of the present disclosure.

### DETAILED DESCRIPTION

A wavelength beam combining device, a direct diode laser device, and a laser processing machine according to embodiments of the present disclosure are described below with reference to the drawings. Parts having the same reference characters appearing in multiple drawings indicate identical or equivalent parts.

The embodiments described below are examples embodying the technical ideas of the present invention, but the present invention is not limited to the described embodiments. The descriptions of dimensions, materials, shapes, relative arrangements, and the like of components are not intended to limit the scope of the present invention thereto but intended to be illustrative. The sizes and positional relationships of members illustrated in the drawings may be exaggerated to facilitate understanding.

In the present specification and claims, polygons, such as triangles or quadrangles, in which the corners of the polygons are rounded, chamfered, beveled, or coved, are referred to as polygons. Not only a shape with such modification at a corner thereof (end of a side) but also a shape with such modification at an intermediate portion of a side thereof is also referred to as a polygon. In other words, a polygon-based shape with partial modification is included in the interpretation of “polygon” described in the present specification and the scope of claims.

### Embodiments

### Wavelength Beam Combining Device

First, a configuration example of a wavelength beam combining device according to an embodiment of the present disclosure is described with reference to FIG. 1. FIG. 1 is a view schematically illustrating a configuration of a wavelength beam combining device according to an exemplary embodiment of the present disclosure. A wavelength beam combining device 100 illustrated in FIG. 1 combines a plurality of laser beams L having mutually different peak wavelengths. The wavelength beam combining device 100 includes an optical member 10, a polarization conversion element 20, a plurality of first light-reflecting members 30a, a plurality of second light-reflecting members 30b, and a diffraction grating 40. The wavelength beam combining device 100 may further include a condensing lens 50 and an optical fiber 60. The optical member 10 in the present embodiment is a polarization beam splitter. Therefore, hereinafter, the optical member 10 is also referred to as a polarization beam splitter BS.

In the accompanying drawings including FIG. 1, an X-axis, a Y-axis, and a Z-axis orthogonal to one another are schematically shown for reference. The direction of an arrow on the X-axis is referred to as a +X direction, and a direction opposite thereto is referred to as a −X direction. When the ±X directions are not distinguished from each other, the ±X directions are simply referred to as X directions. The same applies to a Y direction and a Z direction. This does not limit the orientation of the wavelength beam combining device 100 during use, and the wavelength beam combining device 100 can be oriented in any direction during use.

As will be described in detail below, in the wavelength beam combining device 100 according to the present embodiment, a plurality of first polarized beams L1 and a plurality of second polarized beams L2 linearly polarized in the same specific direction, are obtained from the plurality of laser beams L by a polarization beam splitter BS, the polarization conversion element 20, the plurality of first light-reflecting members 30a, and the plurality of second light-reflecting members 30b. The plurality of first polarized beams L1 and the plurality of second polarized beams L2 are incident on an irradiation region A of the diffraction grating 40 in symmetry with respect to a reference plane P. The reference plane P includes a line normal to the irradiation region A and is parallel to the polarization directions of the first polarized beam L1 and the second polarized beam L2. The diffraction grating 40 coaxially combines the plurality of first polarized beams L1 and the plurality of second polarized beams L2 incident on the irradiation region A in a direction parallel to the line normal to the irradiation region A to form a wavelength-combined beam CL having high power and high light density.

When the polarization directions of the first polarized beam L1 and the second polarized beam L2 are different from each other, it is necessary that one of the polarization directions is converted by another polarization conversion element to be orthogonal to the other polarization direction, and then, the first polarized beam L1 and the second polarized beam L2 whose polarization directions are orthogonal to each other are combined by another polarization beam splitter.

In the wavelength beam combining device 100, the polarization directions of the first polarized beam L1 and the second polarized beam L2 in the formation of the wavelength-combined beam CL are the same as each other, which can eliminate necessity of the polarization combining as described above. Therefore, optical loss due to optical members for polarization combining, including another polarization conversion element and another polarization beam splitter, does not occur. This makes it possible to reduce optical loss in the wavelength beam combining device 100.

The laser beams L and the components of the wavelength beam combining device 100 are described in detail below.

### Laser Beam L

The peak wavelengths of the plurality of laser beams L are different from each other, and may be included in, for example, a predetermined wavelength range described below. The predetermined wavelength range corresponds to at least a part of a wavelength range in which the light absorptivity of a processing target is high. The wavelength width of the predetermined wavelength range may be, for example, equal to or less than 50 nm. When the absolute value of a difference between a maximum value and a minimum value of the peak wavelengths is equal to or less than 50 nm, optical members having wavelength-dependent optical characteristics, such as the polarization beam splitter BS, the polarization conversion element 20, and the condensing lens 50, can be commonly used for a plurality of light beams having different peak wavelengths, regardless of wavelengths. When the processing target is made of copper, the predetermined wavelength range may be, for example, in a range from 430 nm to 480 nm.

FIG. 1 illustrates three laser beams L having mutually different peak wavelengths λ1, λ2 and λ3 as an example. The number of laser beams L is not limited to this example, and may be two, or four or more. As the number of laser beams L is increased, e.g., to 10 or more, the power and the light density of the wavelength-combined beam CL obtained by combining the plurality of laser beams L can be increased. The interval between the peak wavelengths of the plurality of laser beams Lis decreased, so that the number of laser beams L can be increased in the predetermined wavelength range.

Hereinafter, the peak wavelengths of the plurality of laser beams L to be combined may be denoted by λn. “n” as used herein is an integer equal to or larger than 1, and is used as a numerical value for distinguishing the plurality of laser beams L from each other. In the example illustrated in FIG. 1, the relationship of λ1<λ2<λ3 is established.

In FIG. 1, each laser beam L is indicated by a simple straight line. The actual laser beam L is a light beam having an intensity distribution on a plane orthogonal to a traveling direction. The intensity distribution can be approximated by a distribution function such as a Gaussian distribution on the plane orthogonal to the traveling direction of the light beam. The diameter of the light beam is defined, for example, by the size of a cross-sectional area having an intensity 1/e² times or more the intensity at the center of the beam, where e is the base of a natural logarithm. The diameter of the light beam can be in a range of 1 mm to 30 mm, for example.

In the present disclosure, the laser beam L is collimated by an optical system such as a collimator lens. In the drawing, to schematically illustrate the traveling direction of collimated light beams such as the laser beam L, the central axes of the light beams are represented by straight lines. These straight lines may be regarded as indicating light rays passing through the center of each light beam.

The polarization state of the laser beam L may vary depending on a gain medium, a resonator, and an oscillation scheme of a laser light source, for example. A laser beam L in a specific polarization state at the stage of being emitted from a semiconductor laser device may be changed in the polarization state or may be depolarized, while passing through a transmission medium such as an optical fiber.

Each laser beam Lis, for example, light in an unpolarized state. Such a laser beam L is obtained, for example, by causing the semiconductor laser device to emit a laser beam L via an optical fiber as described above.

In the present disclosure, “unpolarized light” refers to light that is not linearly polarized in a predetermined direction. Thus, the “unpolarized light” in a broad sense may include circularly polarized light and elliptically polarized light. In addition, linearly polarized light in a mixed state in which the polarization direction randomly or regularly changes depending on the time or place is also included in the “unpolarized light.”

### Optical Member 10 (Polarization Beam Splitter BS)

The polarization beam splitter BS used as the optical member 10 has a polarization surface 12 for separating each incident laser beam L into light beams in different polarization states. The transmittance and reflectance of the polarization surface 12 vary depending on the polarization state of the laser beam L. The polarization surface 12 of the polarization beam splitter BS can selectively reflect polarized components linearly polarized in a predetermined direction and transmit polarized components linearly polarized in a direction orthogonal to the predetermined direction. The polarization surface 12 is provided with, for example, a polarization-dependent dielectric multilayer film.

In the example illustrated in FIG. 1, the polarization surface 12 of the polarization beam splitter BS is perpendicular to an XZ plane, and the line normal to the polarization surface 12 is on a plane parallel to the XZ plane. The traveling direction of the laser beam L is parallel to the XZ plane. In the present specification, light linearly polarized in the Y direction that is perpendicular to the XZ plane is referred to as “S-polarized light,” and light linearly polarized in a direction parallel to the XZ plane is referred to as “P-polarized light.” In the present specification, the polarization direction of the S-polarized light is also referred to as a “first polarization direction,” and the polarization direction of the P-polarized light is also referred to as a “second polarization direction.” The second polarization direction is orthogonal to the first polarization direction.

In the accompanying drawings, the “S-polarized light” is indicated by a symbol surrounding a cross symbol with a small circle, and the “P-polarized light” is indicated by a symbol with a double-headed arrow. The polarization direction of the “P-polarized light” is parallel to the XZ plane, but perpendicular to the traveling direction of light. Thus, when the traveling direction of the light is rotated by reflection or diffraction while being parallel to the XZ plane, then the polarization direction of the “P-polarized light” is also rotated on a plane parallel to the XZ plane. Accordingly, the “second polarization direction” in the present specification is defined as a direction perpendicular to the traveling direction of light and perpendicular to the first polarization direction.

As illustrated in FIG. 1, the polarization surface 12 of the polarization beam splitter BS reflects components of the S-polarized light and transmits components of the P-polarized light of each laser beam L. Accordingly, the polarization surface 12 of the polarization beam splitter BS separates the plurality of laser beams L into the plurality of first polarized beams L1 that are S-polarized light and a plurality of third polarized beams L3 that are P-polarized light. In this manner, each laser beam L is separated into a corresponding first polarized beam L1 and a corresponding third polarized beam L3.

When the plurality of laser beams L traveling in the +Z direction are incident on the polarization surface 12 of the polarization beam splitter BS, the plurality of first polarized (S-polarized) beams L1 reflected by the polarization surface 12 travel in the −X direction, and the plurality of third polarized (P-polarized) beams L3 transmitted through the polarization surface 12 travel in the +Z direction. The traveling directions of the first polarized (S-polarized) beam L1 and the third polarized (P-polarized) beam L3 may be changed by, for example, an optical member such as a mirror.

Each laser beam L can be incident on the polarization surface 12 at an incident angle in a range of, for example, 40° to 50°, more preferably in a range from 42° to 48°. The closer the incident angle is to 45°, the greater the efficiencies of separating each laser beam L into a corresponding first polarized beam L1 and a corresponding third polarized beam L3. In the wavelength beam combining device 100, all of the plurality of laser beams L may be incident on the polarization beam splitter BS in a parallel state. In this case, the incident angle of each laser beam L with respect to the polarization surface 12 can be 45° to avoid optical loss due to low efficiency of separation of the polarized beams.

When the plurality of laser beams L incident on the polarization beam splitter BS are “unpolarized light”, the laser beams L are separated into the first polarized (S-polarized) beam L1 and the third polarized (P-polarized) beam L3. However, even though the laser beam Lis linearly polarized light in a state of superposition of S-polarized light and P-polarized light, when the polarization direction is not parallel to the X direction or the Y direction, such a laser beam L is separated into the first polarized (S-polarized light) beam L1 and the third polarized (P-polarized light) beam L3. Also, when the plurality of laser beams L incident on the polarization beam splitter BS are linearly polarized in mutually different directions, the plurality of laser beams L can be separated in their entirety into the plurality of first polarized (S-polarized) beams L1 and the plurality of third polarized (P-polarized) beams L3. Accordingly, unless all the plurality of laser beams L incident on the polarization beam splitter BS are linearly polarized in either the X direction or the Y direction, polarization separation by the polarization beam splitter BS can be achieved, and thus the plurality of laser beams L are interpreted in their entirety as “unpolarized light”.

In the example illustrated in FIG. 1, the polarization beam splitter BS is a cube polarization beam splitter, but is not limited to this example. The polarization beam splitter BS may be a plate-type polarization beam splitter or other type of polarization beam splitter.

### Polarization Conversion Element 20

As illustrated in FIG. 1, the polarization conversion element 20 converts the plurality of third polarized beams L3 that are P-polarized light into the plurality of second polarized beams L2 that are S-polarized light. The plurality of second polarized (S-polarized) beams L2 travel in the +Z direction.

The polarization conversion element 20 may be, for example, a half-wave plate. The half-wave plate has birefringence and changes a phase difference between two orthogonal components of an electromagnetic wave traveling in a thickness direction. A slow axis or a fast axis of the half-wave plate is disposed to form an angle of 45° relative to the polarization direction of the P-polarized light, so that the half-wave plate can convert the P-polarized light into S-polarized light.

In this manner, the polarization beam splitter BS and the polarization conversion element 20 are used, so that the plurality of first polarized beams L1 and the plurality of second polarized beams L2 linearly polarized in the same specific direction can be obtained from the plurality of laser beams L that are unpolarized light in their entirety, for example. At this stage, the plurality of first polarized (S-polarized) beams L1 include a plurality of laser beams having different peak wavelengths and not coaxially combined. The same applies to the plurality of second polarized (S-polarized) beams L2.

Unlike the example illustrated in FIG. 1, the polarization surface 12 of the polarization beam splitter BS may reflect components of the P-polarized light and transmit components of the S-polarized light of each laser beam L. In this case, the plurality of third polarized (P-polarized) beams L3 reflected by the polarization surface 12 of the polarization beam splitter BS travel in the −X direction, and the plurality of first polarized (S-polarized) beams L1 transmitted through the polarization surface 12 of the polarization beam splitter BS travel in the +Z direction. The polarization conversion element 20 is disposed at a position through which the plurality of third polarized (P-polarized) beams L3 pass, and converts the plurality of third polarized (P-polarized) beams L3 into the plurality of second polarized (S-polarized) beams L2.

The phase difference formed by the half-wave plate depends on the wavelength of incident light. Accordingly, when three third polarized beams L3 having the peak wavelengths λ1, λ2, and λ3 are transmitted through the half-wave plate, a phase difference of a half-wave is not exactly formed at all the peak wavelengths, and components of the P-polarized light remain in the S-polarized light converted from the P-polarized light. Therefore, the components of the P-polarized light remain in the plurality of second polarized beams L2 emitted from the polarization conversion element 20, and to be more specific, elliptically polarized light may be included.

However, when all of the plurality of peak wavelengths λn are included in a relatively narrow range, for example, a range equal to or less than 50 nm, preferably equal to or less than 10 nm, the difference in phase difference (wavelength dispersion) due to the half-wave plate is sufficiently small. Accordingly, the second polarized beam L2 mainly includes S-polarized components and may partially include P-polarized components.

First Light-Reflecting Member 30a and Second Light-Reflecting Member 30b As illustrated in FIG. 1, each of the plurality of first light-reflecting members 30a reflects the plurality of first polarized beams L1 to be incident on a predetermined irradiation region A of the diffraction grating 40. The plurality of first light-reflecting members 30a correspond one to-one to the plurality of first polarized beams L1. The irradiation region A is a part of the region where a grating structure is provided in the diffraction grating 40, and is located, for example, at the center of the surface of the diffraction grating 40. The position and orientation of each of the plurality of first light-reflecting members 30a are adjusted, so that the plurality of first polarized beams L1 can be directed to the same position of the diffraction grating 40, that is, the irradiation region A.

Similarly, each of the plurality of second light-reflecting members 30b reflects the corresponding one of the plurality of second polarized beams L2 so that the reflected second polarized beam L2 is incident on the predetermined irradiation region A of the diffraction grating 40. Each of the plurality of second light-reflecting members 30b corresponds to a respective one of the plurality of second polarized beams L2. By adjusting the position and orientation of each of the plurality of second light-reflecting members 30b, the plurality of second polarized beams L2 can be directed to the irradiation region A of the diffraction grating 40.

The plurality of first polarized beams L1 and the plurality of second polarized beams L2 reflected as described above travel parallel to the XZ plane and are incident on the irradiation region A in symmetry with respect to the reference plane P.

The first light-reflecting member 30a and the second light-reflecting member 30b may be made of, for example, a dielectric multilayer film having low optical loss. The dielectric multilayer film has a reflectance of almost 100% in a wavelength range called a stopband. When all of the plurality of peak wavelengths λn are included in the stopband, the plurality of first light-reflecting members 30a and the plurality of second light-reflecting members 30b may be made of the same dielectric multilayer film. When optical loss is not considered, the plurality of first light-reflecting members 30a and the plurality of second light-reflecting members 30b may be made of a metal material. The light-reflecting surfaces of the light-reflecting members 30a and 30b inscribe, for example, a circle having a diameter of 1 mm, and can be inscribed in a circle having a diameter of 30 mm.

### Diffraction Grating 40

As illustrated in FIG. 1, the diffraction grating 40 diffracts the plurality of first polarized beams L1 and the plurality of second polarized beams L2 incident on the irradiation region A in symmetry with respect to the reference plane P. As a result, the diffraction grating 40 coaxially combines the plurality of first polarized beams L1 and the plurality of second polarized beams L2 in a direction parallel to the line normal to the irradiation region A to form the wavelength-combined beam CL. Similarly to the first polarized beam L1 and the second polarized beam L2, the wavelength-combined beam CL is S-polarized light.

In some cases, the plurality of first polarized beams L1 and the plurality of second polarized beams L2 are not exactly symmetrical with respect to the reference plane P due to a positional deviation occurring at the time of incidence. Even in this case, when the first and second spots, which will be described below, partially overlap each other, a positional deviation occurring at the time of incidence is allowed. The first spot is a spot formed by the plurality of first polarized beams L1 in a region of the diffraction grating 40 where the grating structure is provided. The second spot is a spot formed by the plurality of second polarized beams L2 in a region of the diffraction grating 40 where the grating structure is provided. The first spot is a region having an intensity equal to or greater than 1/e² times the maximum intensity of the plurality of first polarized beams L1. The second spot is a region having an intensity equal to or greater than 1/e² times the maximum intensity of the plurality of second polarized beams L2. The region of the diffraction grating 40 where the grating structure is provided inscribes, for example, a circle having a diameter of 1 mm, and can be inscribed in a circle having a diameter of 30 mm. The diameter of each of the first and second spots can be, for example, in a range of 1 mm to 30 mm.

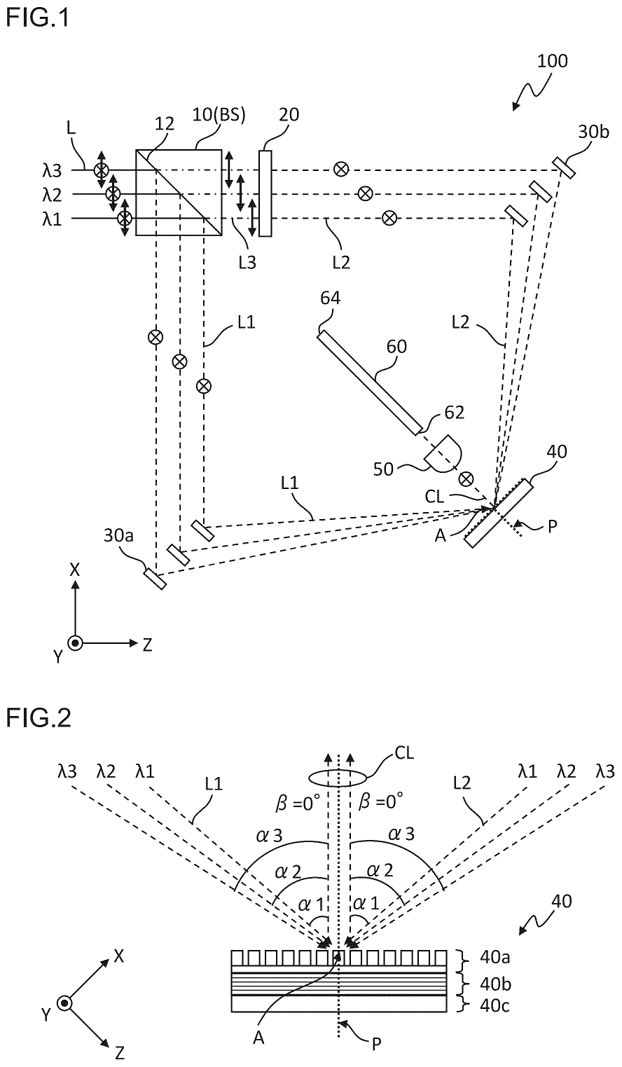

FIG. 2 is a view schematically illustrating an example of a configuration of the diffraction grating 40. FIG. 2 also illustrates diffraction of the plurality of first polarized beams L1 and the plurality of second polarized beams L2. The diffraction grating 40 is a reflective diffraction grating.

As illustrated in FIG. 2, the diffraction grating 40 includes a diffraction portion 40a having a plurality of diffraction grooves parallel to the Y direction that is the first polarization direction, a dielectric multilayer film 40b supporting the diffraction portion 40a, and a substrate 40c supporting the dielectric multilayer film 40b. With the dielectric multilayer film 40b reflecting a light beam transmitted through the diffraction portion 40a, reflected diffracted light is generated at the diffraction grating 40, while transmitted diffracted light is not generated there. The diffraction portion 40a and the substrate 40c may be made of a light-transmissive material such as glass, for example. The plurality of diffraction grooves may be filled with a different member. However, the refractive index of the different member is different from the refractive index of the diffraction portion 40a.

As illustrated in FIG. 2, the diffraction grating 40 has a symmetrical structure with respect to the reference plane P in the irradiation region A. The diffraction grating 40 may be, for example, a so-called laminar diffraction grating in which a plurality of grooves are formed on a flat surface, each of which has a rectangular shape. With the diffraction grating 40 having such a symmetrical structure, the diffraction efficiency of the plurality of first polarized beams L1 and the diffraction efficiency of the plurality of second polarized beams L2 are the same. Accordingly, the diffraction efficiencies of the first polarized beam L1 and the second polarized beam L2 can be set to be equally high.

Even if the diffraction grating 40 does not exactly have a symmetrical structure, it is still acceptable as long as the absolute value of the difference between the diffraction efficiencies of the first polarized beam L1 and the second polarized beam L2 is 5% or less.

The diffraction grating 40 diffracts a light beam, traveling parallel to the XZ plane and incident on the irradiation region A, in a direction parallel to the XZ plane. When the line normal to the irradiation region A is set as a reference, an incident angle of a light beam having a peak wavelength λn is an, and a diffraction angle is β, the following Equation (1) is established.

sin(αn)+sin(β)=N·m·λn (1)

In Equation (1), N is the number of diffraction grooves per 1 mm of the diffraction grating 40, and m is a diffraction order. N may be, for example, in a range of 1000 (/mm) to 5000 (/mm).

In the example illustrated in FIG. 2, because the first-order diffracted light of a light beam incident on the irradiation region A is reflected and diffracted in a direction parallel to the line normal to the irradiation region A, m=1 and β=0°. Because the incident angle αn increases as the peak wavelength λn increases, the relationship of α1<α2<α3 is established as illustrated in FIG. 2. For example, provided that the grating pitch is 600 nm and N=1667, when λ1=460 nm, λ2=465 nm, and λ3=470 nm, α1=50.05°, α2=50.80°, and α3=51.56°.

By appropriately selecting the wavelength λn and the incident angle αn, a plurality of first polarized beams L1 having different peak wavelengths λn can be diffracted in a direction of the same diffraction angle β=0°. The same applies to a plurality of second polarized beams L2 having different peak wavelengths λn. As a result, as illustrated in FIG. 2, the plurality of first polarized beams L1 and the plurality of second polarized beams L2 are coaxially superimposed as reflected diffracted light in a direction parallel to the line normal to the irradiation region A, so that the wavelength-combined beam CL having high power and high light density is formed.

The first polarized beam L1 and the second polarized beam L2 do not need to be polarization-combined in the formation of the wavelength-combined beam CL, so that optical loss due to optical members for polarization combining, including another polarization conversion element and another polarization beam splitter, does not occur. As a result, optical loss in the wavelength beam combining device 100 can be reduced. Moreover, including no optical member for polarization combining allows for reducing the number of components of the wavelength beam combining device 100, so that the configuration of the wavelength beam combining device 100 can be simplified.

The first polarized beam L1 and the second polarized beam L2 that are the S-polarized light are incident on the irradiation region A of the diffraction grating 40. In a case in which the diffraction grating 40 has polarization dependency, when an unpolarized laser beam is incident thereon, the diffraction efficiency is lower depending on the polarized component. In the diffraction grating 40 having a plurality of diffraction grooves parallel to the Y direction that is the first polarization direction, the diffraction efficiency of the S-polarized light is higher than the diffraction efficiency of the P-polarized light. Accordingly, the diffraction grating 40 can effectively diffract the first polarized beam L1 and the second polarized beam L2 that are S-polarized light.

In the diffraction grating 40, zero-order reflected diffracted light that is regular reflected light can be generated for at least one of the plurality of first polarized beams L1. The zero-order reflected diffracted light travels along the optical path of the corresponding second polarized beam L2 in a direction opposite to the traveling direction of the second polarized beam, and can reach the emission position of the laser beam L or the periphery of the emission position. When the laser beam L is emitted from the optical fiber, the zero-order reflected diffracted light is incident on a portion other than the core of the optical fiber and may damage the optical fiber. Similarly, for at least one of the plurality of second polarized beams L2, zero-order reflected diffracted light may be generated by the diffraction grating 40, and a similar event may occur. When each first polarized beam L1 is incident on the irradiation region A at an incident angle in a range of 0° to 44° or in a range of 46° to 90°, and each second polarized beam L2 is incident on the irradiation region A at an incident angle in a range of 0° to 44° or in a range of 46° to 90°, the generation of the zero-order reflected diffracted light described above can be reduced.

The diffraction grating 40 can be designed so that the reflected diffracted light forming the wavelength-combined beam CL is most likely to be generated. However, other reflected diffracted light may also be generated in the diffraction grating 40. The wavelength beam combining device 100 may include a light absorbing member inside a housing that accommodates the components of the wavelength beam combining device 100. The light absorbing member absorbs other reflected diffracted light than the reflected diffracted light forming the wavelength-combined beam CL so that the other reflected diffracted light does not become stray light.

In the example illustrated in FIG. 2, the reflective diffraction grating 40 includes the dielectric multilayer film 40b, but is not limited to this example. In another example, the reflective diffraction grating 40 does not include the dielectric multilayer film 40b, and may include a metal film provided on the surfaces of the plurality of diffraction grooves of the diffraction portion 40a. Even a metal film can reflect a light beam. The substrate 40c may not be provided.

When the laser beam L has a spectral width of Aan to the peak wavelength λn as the substantial center, the spectral width Δλn is preferably smaller. When the spectral width Δλn is increased, the diffraction angle β has a greater range, thus increasing a range of the traveling direction of the wavelength-combined beam CL. The spectral width Δλn is set to, for example, 0.3 nm or less. By combining a plurality of laser beams L having a narrow spectral width Δλn, a wavelength-combined beam CL including a plurality of peak wavelengths in a predetermined wavelength range can be formed, so that the power and light density of the wavelength-combined beam CL can be effectively increased.

### Condensing Lens 50 and Optical Fiber 60

As illustrated in FIG. 1, the condensing lens 50 is disposed at a position at which it receives the wavelength-combined beam CL, condenses the wavelength-combined beam CL, and causes the wavelength-combined beam CL to enter the optical fiber 60. The condensing lens 50 and the optical fiber 60 are located on a side on which the first polarized beam L1 and the second polarized beam L2 are incident, with respect to the diffraction grating 40. When viewed from the Y direction parallel to the first polarization direction, the condensing lens 50 and the optical fiber 60 are surrounded by the optical path of the first polarized beam L1 and the optical path of the second polarized beam L2, and are located inward of these optical paths. This facilitates reduction in the size of the wavelength beam combining device 100 in the two-dimensional direction parallel to the XZ plane.

An optical axis of the condensing lens 50 is parallel to the traveling direction of the wavelength-combined beam CL. A focal point of the condensing lens 50 is located at an incident end surface 62 of the optical fiber 60. The condensing lens 50 may be a single lens or a combination of a plurality of lenses.

The optical fiber 60 emits the wavelength-combined beam CL incident on the incident end surface 62 from an emission end surface 64. The polarization state of the wavelength-combined beam CL may change during passage of the combined wavelength beam CL through the optical fiber 60. Accordingly, even when the wavelength-combined beam CL is in the S-polarized state at the incident end surface 62, the wavelength-combined beam CL is in, for example, an unpolarized state at the emission end surface 64. The optical fiber 60 can have any length and be bent, which allows the wavelength-combined beam CL to be emitted from the emission end surface 64 of the optical fiber 60 in any direction and extracted to the outside of the wavelength beam combining device 100. When the optical fiber 60 is disposed above or below the optical path of the first polarized beam L1 or the optical path of the second polarized beam L2 and extends across them, the optical fiber 60 has a portion overlapping the optical path of the first polarized beam L1 or the optical path of the second polarized beam L2 when viewed from the Y direction parallel to the first polarization direction. This facilitates reduction in the size of the wavelength beam combining device 100 in the Y direction.

As described above, in the wavelength beam combining device 100 according to the present embodiment, the plurality of first polarized beams L1 and the plurality of second polarized beams L2 obtained from the plurality of laser beams L and linearly polarized in the same specific direction are incident on the irradiation region A of the diffraction grating 40 in symmetry with respect to the reference plane P. As a result, the plurality of first polarized beams L1 and the plurality of second polarized beams L2 can be coaxially combined in the direction parallel to the line normal to the irradiation region A as the wavelength-combined beam CL having high power and high light density without polarization combination.

In the wavelength beam combining device 100, necessity of performing polarization-combination of the first polarized beam L1 and the second polarized beam L2 is eliminated, so that optical loss due to an optical member for polarization combination does not occur. Accordingly, the optical loss in the wavelength beam combining device 100 can be reduced. On the other hand, the polarization direction of the coaxially superimposed wavelength-combined beam CL is one uniform direction, and accordingly light output and brightness can also be increased by polarization combination with another wavelength-combined beam in one polarization direction uniformed to be orthogonal to the aforementioned polarization direction.

In the wavelength beam combining device 100 according to the present embodiment, optical members other than the polarization beam splitter BS and the polarization conversion element 20 may be used as long as the plurality of first polarized beams L1 and the plurality of second polarized beams L2 linearly polarized in the same specific direction are obtained from the plurality of laser beams L. Optical members other than the plurality of first light-reflecting members 30a and the plurality of second light-reflecting members 30b may be used as long as the plurality of first polarized beams L1 and the plurality of second polarized beams L2 can be incident on the irradiation region A of the diffraction grating 40 in symmetry with respect to the reference plane P. Optical members other than the condensing lens 50 and the optical fiber 60 may be used as long as the wavelength-combined beam CL is extracted to the outside of the wavelength beam combining device 100.

### Modified Example of Wavelength Beam Combining Device 100

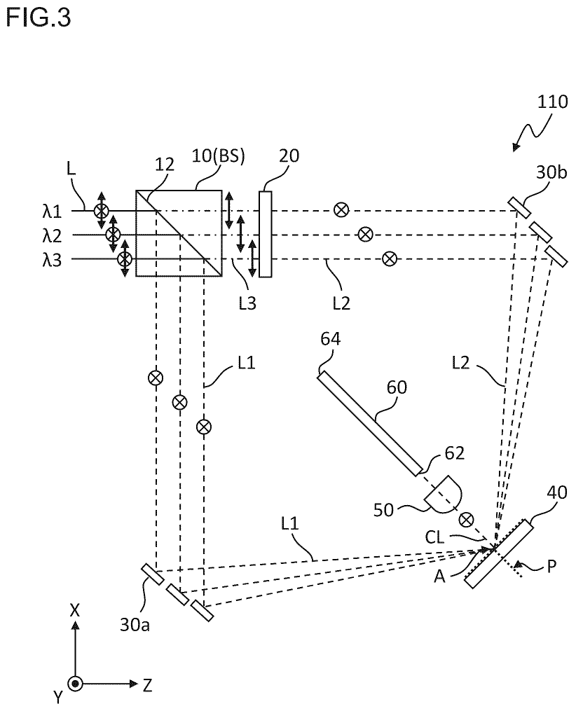

A modified example of the wavelength beam combining device 100 is described below with reference to FIG. 3. FIG. 3 is a diagram schematically illustrating the configuration of the modified example of the wavelength beam combining device 100. A wavelength beam combining device 110 illustrated in FIG. 3 is different from the wavelength beam combining device 100 illustrated in FIG. 1 in the arrangement of the laser beams L having the peak wavelengths λ1, λ2, and λ3 (λ1<λ2<λ3) and the arrangement of the plurality of first light-reflecting members 30a and the plurality of second light-reflecting members 30b.

In the wavelength beam combining device 100 illustrated in FIG. 1, the laser beam L having the shortest peak wavelength λ1 is located on the lower side (−X direction side) of the drawing, and the laser beam L having the longest peak wavelength λ3 is located on the upper side (+X direction side) of the drawing. In contrast to this, in the wavelength beam combining device 110 illustrated in FIG. 3, the laser beam L having the longest peak wavelength λ3 is located on the lower side (−X direction side) of the drawing, and the laser beam L having the shortest peak wavelength λ1 is located on the upper side (+X direction side) of the drawing.

The arrangement of the plurality of first light-reflecting members 30a and the plurality of second light-reflecting members 30b also varies depending on the difference in the arrangement of the plurality of laser beams L. As a result, the incident angle αn when the plurality of first polarized beams L1 are incident on the irradiation region A of the diffraction grating 40, and the incident angle αn when the plurality of second polarized beams L2 are incident on the irradiation region A of the diffraction grating 40 satisfy α1<α2<α3.

Accordingly, also in the wavelength beam combining device 110, similarly to the wavelength beam combining device 100, the plurality of first polarized beams L1 and the plurality of second polarized beams L2 can be coaxially combined as the wavelength-combined beam CL.

In addition, in the wavelength beam combining device 110, the optical path lengths of the polarized beams having the wavelengths λ1, λ2, and λ3 can be made uniform. Accordingly, the spot diameters of the polarized beams in the irradiation region A can be made uniform, and the efficiency in combining the polarized beams into the optical fiber 60 by the condensing lens 50 can be improved.

### Modified Example of Diffraction Grating 40

As illustrated in FIG. 2, the irradiation region A of the diffraction grating 40 is irradiated with the first polarized beam L1 and the second polarized beam L2. In this case, the first polarized beam L1 and the second polarized beam L2 are incident on the same portion of the dielectric multilayer film 40b located immediately below the irradiation region A. As a result, this portion may be locally heated and the diffraction grating 40 may be damaged. The dielectric multilayer film 40b is made of a light-transmissive material that does not easily absorb light. However, when the first polarized beam L1 and the second polarized beam L2 are incident on the same portion of the dielectric multilayer film 40b, this portion may be locally heated.

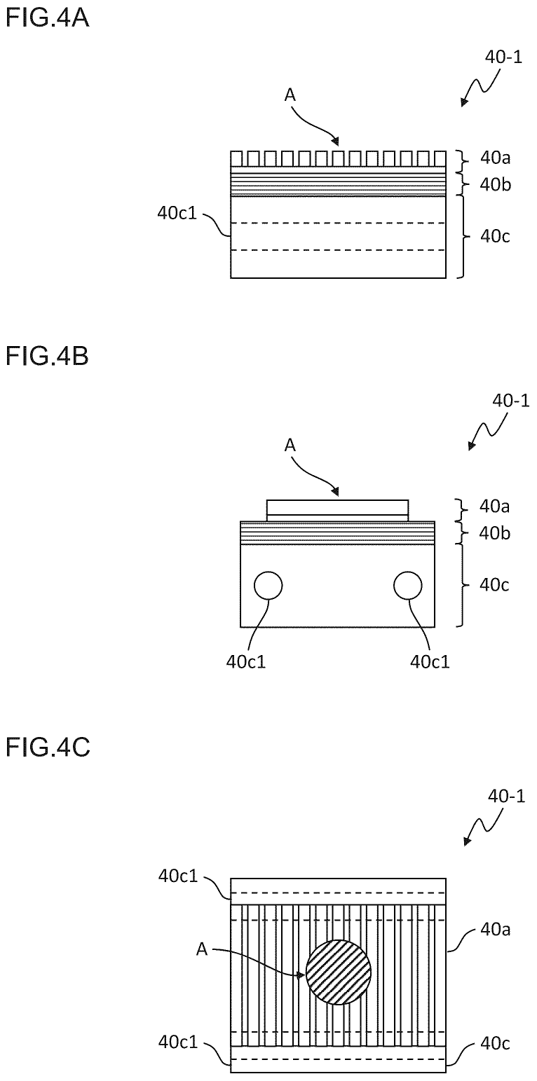

With reference to FIGS. 4A to 4C, a reflective diffraction grating in which the above damage is unlikely to occur is described below as a modified example of the diffraction grating 40. The reflective diffraction grating in this modified example has a cooling structure.

FIGS. 4A, 4B, and 4C are a side view, another side view, and a top view schematically illustrating the configuration of the modified example of the diffraction grating 40, respectively. A hatched circle illustrated in FIG. 4C represents the irradiation region A. A diffraction grating 40-1 illustrated in FIGS. 4A to 4C is different from the diffraction grating 40 illustrated in FIG. 2 in that the substrate 40c has one or more cooling paths 40cl through which cooling water flows as a cooling structure.

With the above cooling structure, heat generated in a portion of the dielectric multilayer film 40b where the first polarized beam L1 and the second polarized beam L2 are concentrated can be released to the outside of the diffraction grating 40 via the cooling path 40cl, and the heated portion can be cooled.

In the example illustrated in FIGS. 4A to 4C, the irradiation region A is located between two cooling paths 40cl when viewed from a direction parallel to the line normal to the irradiation region A. The two cooling paths 40cl extend in a direction parallel to the irradiation region A and perpendicular to the direction in which the diffraction grooves extend. The two cooling paths 40cl are symmetrical to a plane perpendicular to the irradiation region A and bisecting the irradiation region A. With such a configuration, the portion of the dielectric multilayer film 40b where the first polarized beam L1 and the second polarized beam L2 are concentrated is easily cooled evenly.

The number of cooling paths 40cl is not limited to the example illustrated in FIGS. 4A to 4C, and may be one, or three or more. The irradiation region A and the cooling path 40cl may be in any positional relationship when viewed from the direction parallel to the line normal to the irradiation region A. However, it is preferable that the cooling path 40cl does not overlap the irradiation region A when viewed from the direction parallel to the line normal to the irradiation region A. This is because a possibility that heat generated in the portion where the first polarized beam L1 and the second polarized beam L2 are concentrated is excessively transferred to the cooling path 40cl, and that the cooling path 40cl is damaged, can be reduced.

When the diffraction grating 40-1 does not include the dielectric multilayer film 40b, but includes a metal film provided on the surfaces of the plurality of diffraction grooves of the diffraction portion 40a, the metal film is more likely to be damaged by heating due to irradiation with the first polarized beam L1 and the second polarized beam L2 than the dielectric multilayer film 40b. Accordingly, in this case, providing the above cooling structure is more effective.

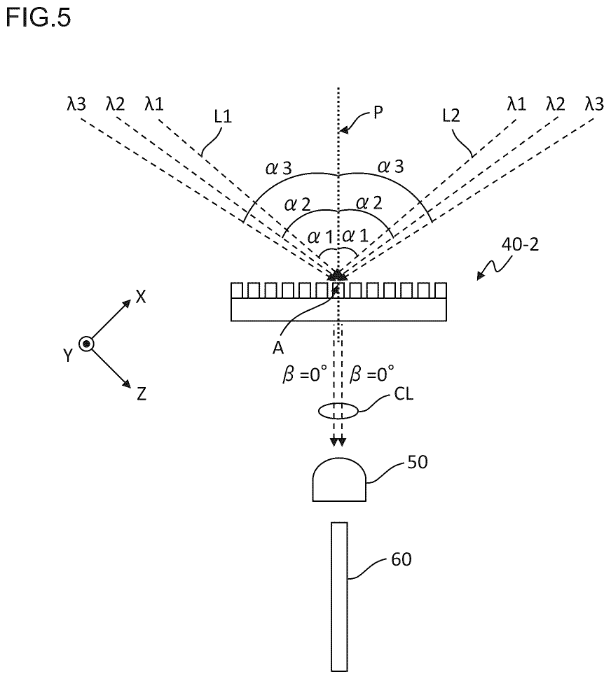

A transmissive diffraction grating is described below as another modified example of the diffraction grating 40 with reference to FIG. 5. FIG. 5 is a view schematically illustrating a configuration of another modified example of the diffraction grating 40. FIG. 5 also illustrates the condensing lens 50 and the optical fiber 60. A diffraction grating 40-2 illustrated in FIG. 5 is a transmissive diffraction grating including a plurality of grooves parallel to the Y direction, and has a symmetrical structure with respect to the reference plane P in the irradiation region A. The diffraction grating 40-2 coaxially combines the plurality of first polarized beams L1 and the plurality of second polarized beams L2 as transmitted diffracted light in the direction parallel to the line normal to the irradiation region A to form the wavelength-combined beam CL.

The condensing lens 50 is disposed at such a position as to receive the wavelength-combined beam CL, condenses the wavelength-combined beam CL, and inputs the wavelength-combined beam CL to the optical fiber 60. Accordingly, the condensing lens 50 and the optical fiber 60 are located on a side opposite to the side on which the first polarized beam L1 and the second polarized beam L2 are incident with respect to the diffraction grating 40-2.

The diffraction grating 40-2 can be designed so that the transmitted diffracted light forming the wavelength-combined beam CL is most likely to be generated. However, in the diffraction grating 40-2, other transmitted diffracted light may also be generated and reflected diffracted light may further be generated. The wavelength beam combining device 100 may include a light absorbing member inside a housing that accommodates components of the wavelength beam combining device 100. The light absorbing member absorbs other diffracted light than the transmitted diffracted light forming the wavelength-combined beam CL so that the other diffracted light does not become stray light.

Alternatively, the diffraction grating 40-2 may coaxially superimpose the plurality of first polarized beams L1 and the plurality of second polarized beams L2 as reflected diffracted light, instead of transmitted diffracted light, to form the wavelength-combined beam CL. In this case, the diffraction grating 40-2 can be designed so that the reflected diffracted light forming the wavelength-combined beam CL is most likely to be generated. However, in the diffraction grating 40-2, other reflected diffracted light may also be generated, and transmitted diffracted light may further be generated. The wavelength beam combining device 100 may include a light absorbing member inside a housing that accommodates components of the wavelength beam combining device 100. The light absorbing member absorbs other diffracted light than the reflected diffracted light forming the wavelength-combined beam CL so that the other diffracted light does not become stray light.

When the wavelength-combined beam CL is formed by the transmitted diffracted light or the reflected diffracted light by using the diffraction grating 40-2, unlike the example illustrated in FIG. 5, the diffraction grating 40-2 may be disposed upside down so that the plurality of diffraction grooves face the direction of the condensing lens 50.

### Direct Diode Laser Device

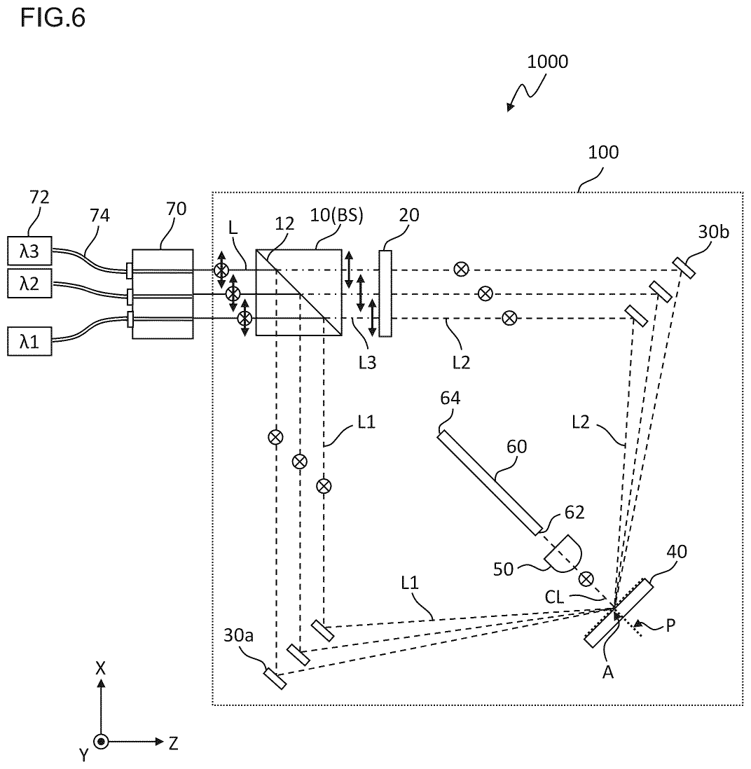

A configuration example of a DDL device according to an embodiment of the present disclosure is described below with reference to FIG. 6. FIG. 6 is a view schematically illustrating a configuration of the DDL device according to an exemplary embodiment of the present disclosure. A DDL device 1000 illustrated in FIG. 6 includes the wavelength beam combining device 100 illustrated in FIG. 1 and a plurality of semiconductor laser devices 72, each of which emits laser light corresponding to a respective one of the plurality of laser beams L. The DDL device 1000 further includes an optical fiber array device 70 configured to cause the laser light emitted from each semiconductor laser device 72 to be formed into a respective one of the plurality of laser beams L. Instead of the wavelength beam combining device 100 illustrated in FIG. 1, the wavelength beam combining device 110 illustrated in FIG. 3 may be used.

In the example illustrated in FIG. 6, the number of semiconductor laser devices 72 is three, but is not limited to this example. The number of semiconductor laser devices 72 is determined in accordance with a required light output or irradiance. The wavelength of the laser light emitted from the semiconductor laser device 72 may also be selected in accordance with a material to be processed.

The laser light emitted from each semiconductor laser device 72 is optically combined into a corresponding optical fiber 74 of the optical fiber array device 70. The plurality of semiconductor laser devices 72 are configured to oscillate at mutually different peak wavelengths. Even though the laser light emitted from each semiconductor laser device 72 is linearly polarized light, when the optical fiber 74 is not a polarization-maintaining fiber, the polarization state of the laser light changes as the laser light passes through the optical fiber 74. Accordingly, each of the plurality of laser beams L formed by the optical fiber array device 70 is unpolarized light.

Examples of the semiconductor laser device 72 include an external cavity laser (ECL) device, a distributed feedback (DFB) laser device, and a distributed Bragg reflector (DBR) laser device.

The optical fiber array device 70 is used, and thus the optical fibers 74 can be arrayed, and an emission angle of the laser beam L can be easily adjusted. As a result, the plurality of laser beams L are easily emitted in parallel with high accuracy from the optical fiber array device 70. An optical fiber extending from the semiconductor laser device 72 can also be fused and connected to the optical fiber 74 of the optical fiber array device 70. The optical fiber array device 70 includes a lens system that collimates laser light emitted from a tip of each optical fiber 74.

In the DDL device 1000 according to the present embodiment, even though the laser light emitted from the plurality of semiconductor laser devices 72 is brought into an unpolarized state by the optical fiber array device 70, the wavelength beam combining device 100 can form the wavelength-combined beam CL from the plurality of unpolarized laser beams L.

### Laser Processing Machine

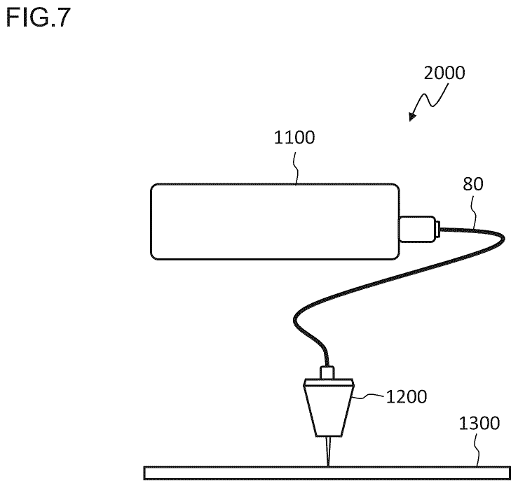

A configuration example of a laser processing machine according to an embodiment of the present disclosure is described below with reference to FIG. 7. FIG. 7 is a view illustrating the configuration of the laser processing machine according to an exemplary embodiment of the present embodiment. A laser processing machine 2000 illustrated in FIG. 7 includes a light source device 1100, an optical transmission fiber 80 extending from the light source device 1100 into which a wavelength-combined beam CL emitted from the light source device 1100 is combined, and a processing head 1200 connected to the optical transmission fiber 80. The processing head 1200 irradiates a target 1300 with the wavelength-combined beam CL emitted from the optical transmission fiber 80. The light source device 1100 is the DDL device 1000 illustrated in FIG. 6.

In the example illustrated in FIG. 7, the number of light source devices 1100 is one, but the number of light source devices 1100 is not limited to this example. The processing head 1200 may be connected to a plurality of light source devices 1100 via the optical transmission fiber 80.

In the laser processing machine 2000 according to the present embodiment, because a high-power laser beam is generated by wavelength beam combining and is efficiently combined into an optical fiber, a high-light density laser beam having excellent beam quality can be obtained with high energy conversion efficiency.

Laser beams emitted from the processing head 1200 may include laser beams other than laser beams emitted from the semiconductor laser device 72 illustrated in FIG. 6 and combined. For example, although the peak wavelengths of the laser beams emitted from the semiconductor laser device 72 and wavelength-combined are included in a wavelength range from 430 nm to 480 nm, laser beams having peak wavelengths of near infrared may be superimposed, for example. Depending on a material to be processed, a laser beam having a wavelength at which the light absorptivity of the material is high can be superimposed as appropriate.

A wavelength beam combining device, a direct diode laser device, and a laser processing machine of the present disclosure can be widely used in applications requiring high power and high light density laser light with high beam quality, for example, cutting, drilling, local heat treatment, surface treatment of various materials, welding of metal, and 3D printing.

What is claimed is:

1. A wavelength beam combining device for combining a plurality of laser beams having mutually different peak wavelengths, comprising:
a diffraction grating configured to diffract a plurality of first polarized beams linearly polarized in a first polarization direction and a plurality of second polarized beams linearly polarized in the first polarization direction, the plurality of first polarized beams and the plurality of second polarized beams being obtained from the plurality of laser beams, wherein:
the plurality of first polarized beams and the plurality of second polarized beams are incident on an irradiation region of the diffraction grating in symmetry with respect to a reference plane including a line normal to the irradiation region and parallel to the first polarization direction, and
the diffraction grating comprises a symmetrical structure with respect to the reference plane in the irradiation region and is configured to superimpose the plurality of first polarized beams and the plurality of second polarized beams incident on the irradiation region in a direction parallel to the line normal to the irradiation region to form a wavelength-combined beam.

2. The wavelength beam combining device according to claim 1, comprising:
an optical member configured to separate the plurality of laser beams into the plurality of first polarized beams linearly polarized in the first polarization direction and a plurality of third polarized beams linearly polarized in a second polarization direction orthogonal to the first polarization direction; and
a polarization conversion element configured to convert the plurality of third polarized beams into the plurality of second polarized beams linearly polarized in the first polarization direction.

3. The wavelength beam combining device according to claim 1, further comprising:
a plurality of first light-reflecting members, each of which is configured to reflect a corresponding one of the plurality of first polarized beams to be incident on the irradiation region of the diffraction grating; and
a plurality of second light-reflecting members, each of which is configured to reflect a corresponding one of the plurality of second polarized beams to be incident on the irradiation region of the diffraction grating.

4. The wavelength beam combining device according to claim 1, wherein the diffraction grating is a laminar diffraction grating.

5. The wavelength beam combining device according to claim 1, wherein the diffraction grating comprises a plurality of diffraction grooves parallel to the first polarization direction.

6. The wavelength beam combining device according to claim 1, wherein:
each of the plurality of first polarized beams is incident on the irradiation region at an incident angle in a range of 0° to 44° or in a range of 46° to 90°, and
each of the plurality of second polarized beams is incident on the irradiation region at an incident angle in a range of 0° to 44° or in a range of 46° to 90°.

7. The wavelength beam combining device according to claim 2, wherein:
the optical member has a polarization surface that separates the plurality of laser beams into the plurality of first polarized beams and the plurality of third polarized beams, and
each of the plurality of laser beams is incident on the polarization surface at an incident angle in a range of 40° to 50°.

8. The wavelength beam combining device according to claim 1, wherein the diffraction grating is a reflective diffraction grating and comprises a cooling structure.

9. The wavelength beam combining device according to claim 8, wherein:
the cooling structure is one or more cooling paths, and
the one or more cooling paths do not overlap the irradiation region when viewed from a direction parallel to the line normal to the irradiation region.

10. The wavelength beam combining device according to claim 1, wherein each of the plurality of laser beams is emitted from a semiconductor laser device via an optical fiber.

11. The wavelength beam combining device according to claim 1, further comprising:
a condensing lens and an optical fiber, wherein:
the condensing lens is configured to condense the wavelength-combined beam and to input the wavelength-combined beam to the optical fiber.

12. The wavelength beam combining device according to claim 11, wherein the condensing lens and the optical fiber are surrounded by an optical path of the plurality of first polarized beams and an optical path of the plurality of second polarized beams when viewed from a direction parallel to the first polarization direction.

13. The wavelength beam combining device according to claim 11, wherein the optical fiber comprises a portion overlapping an optical path of the plurality of first polarized beams and an optical path of the plurality of second polarized beams when viewed from a direction parallel to the first polarization direction.

14. A direct diode laser device comprising:
the wavelength beam combining device according to claim 1; and
a plurality of semiconductor laser devices, each of which is configured to emit laser light corresponding to a respective one of the plurality of laser beams.

15. The direct diode laser device according to claim 14, further comprising:
an optical fiber array device configured to cause the laser light emitted from each of the plurality of semiconductor laser devices to be formed into a respective one of the plurality of laser beams.

16. A laser processing machine comprising:
at least one direct diode laser device according to claim 14;
an optical transmission fiber into which the wavelength-combined beam emitted from the at least one direct diode laser device is combined; and
a processing head connected to the optical transmission fiber.
